(19) United States
(12) Patent Application Publication
(10) Pub. No.: US 2016/0026097 A1
(43) Pub. Date: Jan. 28, 2016

(54) VIBRATION CONTROL DEVICE, LITHOGRAPHY APPARATUS, AND ARTICLE MANUFACTURING METHOD

(71) Applicant: CANON KABUSHIKI KAISHA, Tokyo (JP)

(72) Inventor: Wataru Tamura, Kasukabe-shi (JP)

(21) Appl. No.: 14/803,146

(22) Filed: Jul. 20, 2015

(30) Foreign Application Priority Data
Jul. 22, 2014 (JP) 2014-148536

(51) Int. Cl. G03F 7/20; F16F 15/00

(52) U.S. Cl. CPC G03F 7/70775; F16F 15/002; F16F 15/005

(57) ABSTRACT

A detecting system of a vibration control device provided herein includes a second object, a second spring mechanism that supports the second object, a third object, a third spring mechanism, a first detector that detects displacement of the third object with respect to the second object, a second driving member, and a feedback control member that perform feedback control on the second driving member based on the output of the first detector. A two-degree-of-freedom system, including the second object and the third object, vibrates by a first vibration mode that accompanies a translation motion and a second vibration mode that accompanies atilt motion according to a natural frequency, and a servomotor control frequency of the feedback control member is higher than the natural frequency of the first vibration mode and lower than the natural frequency of the second vibration mode.

### BACKGROUND OF THE INVENTION

1. Field of the Invention

The present invention relates to a vibration control device, a lithography apparatus, and an article manufacturing method.

2. Description of the Related Art

In a lithography apparatus that transfers or forms ultrafine patterns, vibration that is transmitted to the inside of the apparatus from a floor onto which the apparatus is disposed causes the deterioration of overlay accuracy and a resolution (transfer) performance. Accordingly, in the conventional lithography apparatus, in order to reduce the influence of the floor vibration, a surface plate that is a body part is supported via a vibration control device (vibration isolation device). The conventional vibration control device has a gas spring that supports the surface plate (object to be controlled), further configures a speed feedback control system by using an acceleration sensor that detects acceleration of the surface plate and an actuator that applies a force to the surface plate, and performs vibration damping. However, if the vibration damping is performed by a speed feedback control system, a natural frequency of the vibration control device that depends on the natural frequency of the gas spring is at least about 3 to 5 Hz. Accordingly, the natural frequency of the vibration control device needs to be further lowered in order to isolate vibrations having even lower frequencies.

Japanese Patent Laid-Open No. 2012-97786 discloses another vibration control device for controlling the vibration of a first object (object to be controlled). This vibration control device has a first spring mechanism that supports the first object, a first actuator that displaces the first object, and a detecting system that detects the position of the first object. The detecting system has a second object, a third object, a second spring mechanism that supports the second object on the third object, and a third spring mechanism that supports the third object on a second base. Additionally, the detecting system has a displacement sensor that detects vertical relative displacement between the second object and the third object, a second actuator that displaces the third object, and a displacement sensor that detects the vertical relative displacement between the first object and the second object. Here, the vibration control device performs feedback control on the second actuator based on the detected result for the relative displacement between the second object and the third object. Subsequently, the vibration control device performs the feedback control on the first actuator based on the detected result for the relative displacement between the first object and the second object, and decreases the vibration transmitted to the first object from the floor.

As stated above, the Japanese Patent Laid-Open No. 2012-97786 has a two-degree-of-freedom system that supports the second object and the third object in series by the spring mechanism. However, the Japanese unexamined patent application publication No. 2012-97786 does not disclose any relation between a servomotor control frequency when the feedback control on the second actuator is performed and a natural frequency of the two-degree-of-freedom system. An inventor of the present application focused on a feature in which the vibration occurs by a first vibration mode that accompanies a translational motion and a second vibration mode that accompanies a tilt motion, according to the natural frequency of the two-degree-of-freedom system. Subsequently, the inventor of the present application discovered that oscillation of the device can be caused when the feedback control on the second actuator is simply performed without taking these vibration modes into account.

### SUMMARY OF THE INVENTION

The present invention provides, for example, a vibration control device that controls vibration of a object to be controlled by using a two-degree-of-freedom system and is thereby advantageous in suppressing oscillation.

The present invention is a vibration control device comprising: a first object; a first spring mechanism for supporting the first object; a detecting system for detecting a position of the first object; and a first driving member for applying a force to the first object, wherein the vibration control device is configured to control the first driving member based on the output of the detecting system to control vibration of the first object, wherein the detecting system includes: a second object; a second spring mechanism that supports the second object; a third object that supports the second spring mechanism; a third spring mechanism that supports the third object; a first detector that detects displacement of the third object with respect to the second object; a second driving member that applies a force to the third object; and a feedback control member that is configured to perform feedback control on the second driving unit based on the output of the first detector, wherein a two-degree-of-freedom system including the second object and the third object vibrates by a first vibration mode that accompanies a translation motion or a second vibration mode that accompanies a tilt motion, according to a natural frequency, and wherein a servomotor control frequency of the feedback control member is higher than the natural frequency of the first vibration mode and lower than the natural frequency of the second vibration mode.

Further features of the present invention will become apparent from the following description of exemplary embodiments (with reference to the attached drawings).

### BRIEF DESCRIPTION OF THE DRAWINGS

FIG. 1 illustrates a configuration of a vibration control device according to one embodiment of the present invention.

FIGS. 2A and 2B are perspective diagrams illustrating a configuration of a reference portion.

FIG. 3A to 3C illustrate a shape of a first plate spring that configures a spring mechanism in the reference portion.

FIGS. 4A and 4B illustrate a shape of a second plate spring that configures the spring mechanism in the reference portion.

FIGS. 5A and 5B illustrate a shape of a third plate spring that configures the spring mechanism in the reference portion.

FIGS. 6A to 6C are diagrams for explaining a plurality of vibration modes in the reference portion.

### DESCRIPTION OF THE EMBODIMENTS

Hereinafter, a description will be given of embodiments for performing the present invention with reference to the attached drawings.

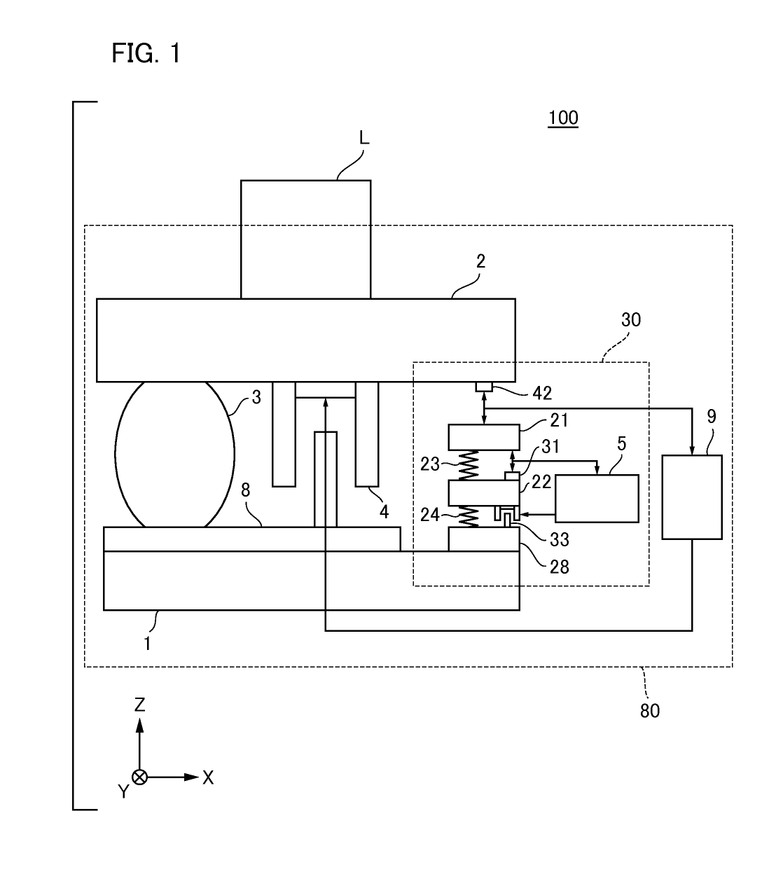

First, a description will be given of a vibration control device according to one embodiment of the present invention. The vibration control device according to the present embodiment controls vibration that can be transmitted from one object to another object, and here the device is disposed in a lithography apparatus that is employed for a lithography process in a manufacturing processes of a semiconductor device, a liquid crystal display device, and the like. Note that the “vibration control device” is sometimes referred to as a “vibration isolation device”. FIG. 1 is a schematic diagram illustrating a configuration of a lithography apparatus 100 that includes a vibration control device 80 according to the present embodiment. Note that, in the drawing, the X-axis and the Y-axis that is orthogonal to the X-axis are positioned in a plane perpendicular to the Z-axis that is in a vertical direction. The lithography apparatus 100 includes a processing unit L that performs pattern formation processing with respect to a substrate that is an object to be processed, and the vibration control device 80 that controls the vibration of a first object 2 serving as at least a part of configuration components that configure the processing unit L.

The processing unit L is a main body or a part of a unit that forms patterns on the substrate, and the first object 2 is a supporting unit (for example, surface plate) that supports (loads) the unit. When the lithography apparatus 100 is an imprint apparatus in which an uncured layer on the substrate is shaped by using a mold, the mold is subsequently released from the layer, and the patterns are formed on the substrate, the unit can include a holding unit (substrate holder, mold holder, or the like) that holds at least either of the substrate or the mold. Additionally, when the apparatus is a drawing apparatus that projects charged particle beams onto a layer on the substrate that is sensitive to the charged particle beams, the unit can include a holding unit (projection system housing, substrate holder, or the like) that holds at least one of a projection system that projects the charged particle beams or the substrate. Additionally, when the apparatus is an exposure apparatus that projects light onto the layer on the substrate that is sensitive to the lights and exposes the layer, the unit can include a holding unit (lens barrel, original holder, substrate holder, or the like) that holds at least one of a projection system that projects lights, an original, and the substrate. Subsequently, the processing unit L is supported by the first object 2 that is supported via a first spring mechanism 3 and a first driving unit (first driving member) 4, with respect to a second base 8 that supports the entire lithography apparatus 100.

The vibration control device 80 is disposed between a floor 1 serving as a vibration source and the first object 2 serving as an object to be controlled (object to be vibration-isolated), regulates the first spring mechanism 3, a first driving unit 4, and a reference position, and includes a reference portion 30 that configures a detecting system that detects the position of the first object 2. The first spring mechanism 3 includes, for example, a gas spring (air spring) as an elastic member. The first driving unit 4 includes, for example, a linear motor, applies a force to the first object 2, and displaces it with reference to a second base 8 that is mounted (fixed) on the floor 1.

The reference portion 30 has a two-degree-of-freedom system that supports a second object (reference object) 21 and a third object 22 in series, by using a second spring mechanism 23 and a third spring mechanism 24. Additionally, the reference portion 30 can include a second driving unit (second driving member) 33, a base 28, a first detector 31, a first compensator 5, a second detector 42, and a second compensator 9. The second object 21 is displaceably supported by the third object 22 via the second spring mechanism 23. The third object 22 is displaceably supported by the base 28 via the third spring mechanism 24. The second driving unit 33 applies a force to the third object 22 and displaces the third object 22 with respect to the base 28. The first detector 31 is disposed at a position where the second object 21 faces the third object 22, or disposed at a position where the third object 22 faces the second object 21, and detects the displacement of the third object 22 with respect to the second object 21. Subsequently, the first detector 31 outputs the detected displacement to the first compensator 5 as a first detection signal. The second detector 42 is disposed at a position where the first object 2 faces the second object 21, and outputs relative displacement between the first object 2 and the second object 21 (relative position, or position or displacement of either one of the first object 2 or the second object 21 with respect to the other one) to the second compensator 9 as a second detection signal.

Here, a first feedback control system (feedback control unit) performs position feedback control on the third object 22 such that the relative displacement between the second object 21 and the third object 22 is fixed, based on the first detection signal. The first compensator 5 is included in the first feedback control system, calculates (generates) a first operation amount to the second driving unit 33 such that a damping force is applied to the third object 22 based on the first detection signal and a target value, and outputs it. In contrast, a second feedback control system performs the position feedback control on the first object 2 based on the second detection signal. The second compensator 9 is included in the second feedback control system and calculates (generates) a second operation amount to the first driving unit 4 based on the second detection signal and the target value, and outputs it. Note that a PID compensator can be used as the first compensator 5 and the second compensator 9.

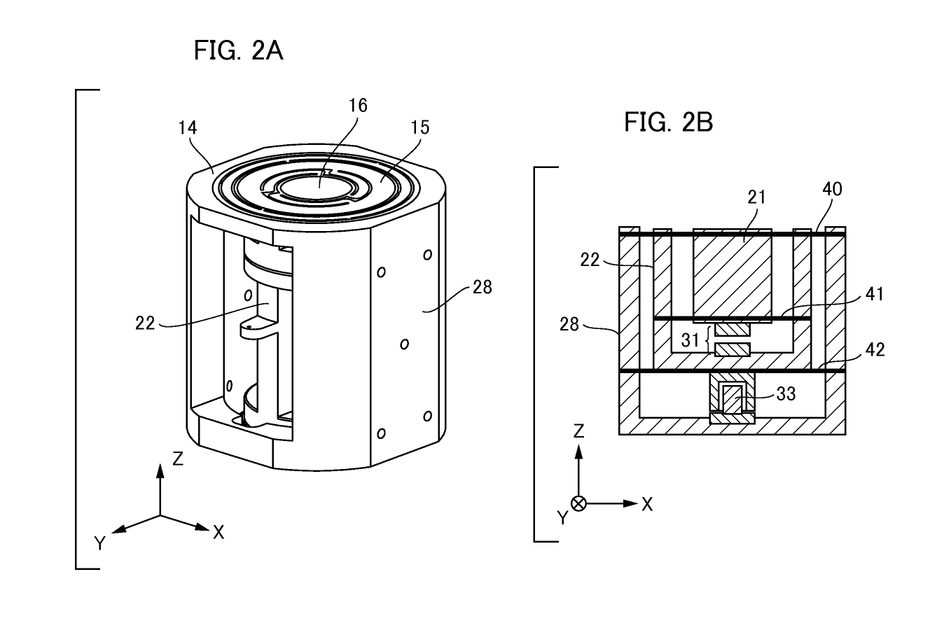

Next, a description will be given of a further specific configuration of the reference portion 30. FIGS. 2A and 2B illustrate the configuration of the reference portion 30, wherein FIG. 2A is a perspective diagram of the entire reference portion 30 and FIG. 2B is a schematic cross-sectional diagram. The second object 21 is a column shaped (includes a substantially column shape) object, and its central axis (hereinafter, referred to as “reference axis”) passes through the barycenter of the second object 21 and the barycenter of the third object 22, and extends in the Z-axis direction where the second object 21 and third object 22 align with each other (corresponding to the central axis shown in FIGS. 6A to 6C). The third object 22 is a circular tube-shaped object in which one end face (XY-plane in the +Z-axis direction) is open and the other end face (XY-plane in the −Z-axis direction) is closed, and its central axis is coaxial to the reference axis and configured so as to cover the side face of the second object 21. Due to this shape, the third object 22 can support the second object 21 from a perpendicular direction with respect to the reference axis. Additionally, in a manner similar to the third object 22, the base 28 is a circular tube-shaped object in which one end face (XY-plane in the +Z-axis direction) is open and the other end face (XY-plane in the −Z-axis direction) is closed, and its central axis is coaxial to the reference axis and configured so as to cover the side face of the third object 22. By this shape, the base 28 can support the third object 22 from a perpendicular direction with respect to the reference axis. Subsequently, the first detector 31, in which a measurement direction is a displacement direction of the second object 21, is disposed between the second object 21 and the third object 22. Additionally, the second driving unit 33 is disposed between the third object 22 and the base 28.

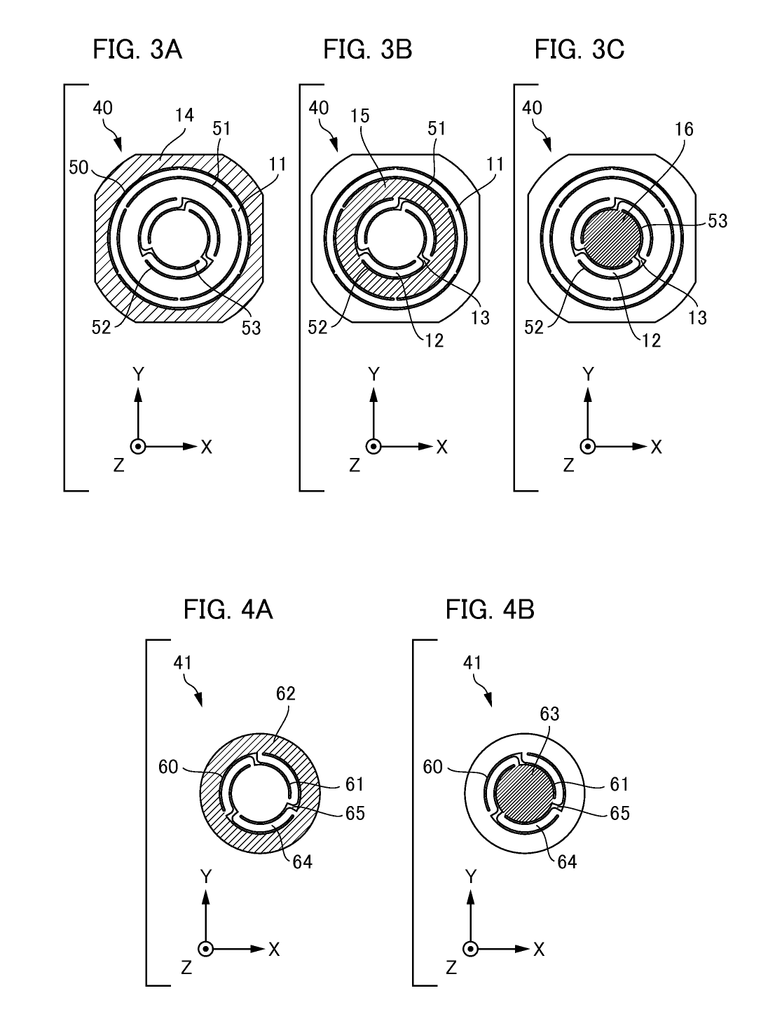

Additionally, the reference portion 30 includes a first plate spring 40, a second plate spring 41, and a third plate spring 42, onto each of which a plurality of through grooves is formed, serving as three metallic plate elastic members. FIGS. 3A to 3C illustrate a planar shape of the first plate spring 40. The first plate spring 40 is connected to the second object 21, the third object 22, and the base 28, and it can be disposed, for example, at the end of the reference portion 30 in the positive side of the Z-axis direction. As shown in FIGS. 3A to 3C, the planar shape of the outermost peripheral part of the first plate spring 40 fits, for example, the outer peripheral shape of the reference portion 30 (base 28). Additionally, the first plate spring 40 has a plurality of through grooves (cut-out portions) in the inside that are each discontinuously and concentrically provided around the reference axis. In the present embodiment, a total of four through grooves having different radiuses, that is, a first through groove 50, a second through groove 51, a third through groove 52, and a fourth through groove 53 are present. The first through groove 50 is present outermost from the reference axis among the four through grooves, and the second through groove 51, the third through groove 52, and the fourth through groove 53 are present in order toward the inside (toward the reference axis).

FIG. 3A illustrates a first connection area 14 with oblique lines, which is adjacent to the outer periphery of the first through groove 50 in the XY-plane of the first plate spring 40. The base 28 is connected to the first connection area 14 as shown in FIG. 2B. Subsequently, the first through groove 50 has a shape along the inner periphery of the base 28. FIG. 3B illustrates a second connection area 15 with oblique lines, which is adjacent to the inner periphery of the second through groove 51, and adjacent to the outer periphery of the third through groove 52, in the XY-plane of the first plate spring 40. The third object 22 is connected to the second connection area 15 as shown in FIG. 2B. Subsequently, the second through groove 51 has a shape along the outer periphery of the third object 22, and the third through groove 52 has a shape along the inner periphery of the third object 22. Additionally, FIG. 3C illustrates a third connection area 16 with oblique lines, which is positioned at the inner periphery of the fourth through groove 53, in the XY-plane of the first plate spring 40. The second object 21 is connected to the third connection area 16 as shown in FIG. 2B. Subsequently, the fourth through groove 53 has a shape along the outer periphery of the second object 21.

Additionally, an area 11 that is adjacent to the inner periphery of the first through groove 50 and adjacent to the outer periphery of the second through groove 51 is a first beam area that makes the relative position between the first connection area 14 and the second connection area 15 in the Z-axis direction variable. The first plate spring 40 can generate an action as a first spring due to the occurrence of the displacement in the Z-axis direction, that is, the occurrence of deflection, in the first beam area 11. Additionally, an area 12 that is adjacent to the inner periphery of the third through groove 52 and adjacent to the outer periphery of the fourth through groove 53 is a second beam area that makes the relative position between the second connection area 15 and the third connection area 16 in the Z-axis direction variable. The first plate spring 40 can generate an action as a second spring due to the occurrence of the displacement in the Z-axis direction, that is, the occurrence of deflection, in the second beam area 12.

FIGS. 4A and 4B illustrate a planar shape of the second plate spring 41. The second plate spring 41 is connected to the second object 21 and the third object 22, and it can be disposed, for example, such that the connecting part with the second object 21 is positioned at the end of the second object 21 in the negative side of the Z-axis direction. The planar shape of the outermost periphery part of the second plate spring 41 fits, for example, the outer periphery shape of the third object 22, as shown in FIGS. 3A to 3C. Additionally, in a manner similar to the first plate spring 40, the second plate spring 41 also has a plurality of through grooves in the inside that are each discontinuously and concentrically provided around the reference axis. In the present embodiment, a total of two through grooves having different radiuses, that is, a first through groove 60 and a second through groove 61, are present. The first through groove 60 is present outermost from the reference axis in the two through grooves, and its shape and size are identical to the third through groove 52 on the first plate spring 40. In contrast, the second through groove 61 is present more toward the inside than the first through groove 60, and its shape and size are identical to the fourth through groove 53 on the first plate spring 40.

FIG. 4A illustrates a first connection area 62 with oblique lines, which is adjacent to the outer periphery of the first through groove 60 in the XY-plane of the second plate spring 41. The third object 22 is connected to the first connection area 62 as shown in FIG. 2B. Additionally, FIG. 4B illustrates a second connection area 63 with oblique lines, which is positioned in the inner periphery of the second through groove 61, in the XY-plane of the second plate spring 41. The second object 21 is connected to the second connection area 63 as shown in FIG. 2B. Subsequently, the first through groove 60 has a shape along the inner periphery of the third object 22, and the second through groove 61 has a shape along the outer periphery of the second object 21.

Additionally, an area 64 that is adjacent to the inner periphery of the first through groove 60 and adjacent to the outer periphery of the second through groove 61 is a variable beam area that makes the relative position between the first connection area 62 and the second connection area 63 in the Z-axis direction variable. The second plate spring 41 can generate an action as a spring due to the occurrence of the displacement in the Z-axis direction, that is, the occurrence of deflection, in the beam area 64.

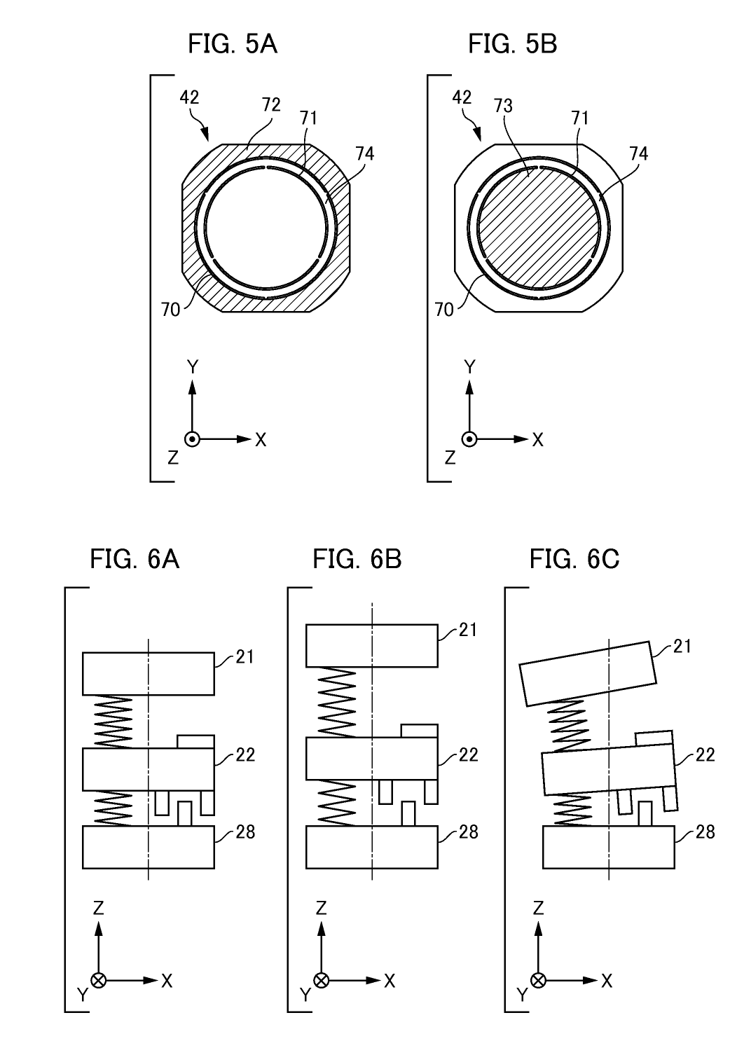

FIGS. 5A and 5B illustrate a planar shape of the third plate spring 42. The third plate spring 42 is connected to the third object 22 and the base 28, and, for example, it can be disposed such that the connection part with the third object 22 is positioned at the end of the third object 22 in the negative side of the Z-axis direction. As shown in FIGS. 5A and 5B, the planar shape of the outermost periphery part of the third plate spring 42, for example, fits the outer periphery shape of the reference portion 30 (base 28), in a manner similar to the first plate spring 40. Additionally, the third plate spring 42 also has a plurality of through grooves that is discontinuously and concentrically provided each other around the reference axis, in the manners similar to the first plate spring 40 and the second plate spring 41. In the present embodiment, totally two through grooves, a first through groove 70 and a second through groove 71, having different radiuses each other exist. The first through groove 70 is present outermost from the reference axis in the two through grooves, and its shape and size are identical to the first through groove 50 on the first plate spring 40. In contrast, the second through groove 71 exists more toward the inside than the first through groove 70, and its shape and size are identical to the second through groove 51 on the first plate spring 40.

FIG. 5A illustrates a first connection area 72 with oblique lines, which is adjacent to the outer periphery of the first through groove 70 in the XY-plane of the third plate spring 42. The base 28 is connected to the first connection area 72 as shown in FIG. 2B. Additionally, FIG. 5B illustrates a second connection area 73 with oblique lines, which is in the inner periphery of the second through groove 71 in the XY-plane of the third plate spring 42. The third object 22 is connected to the second connection area 73 as shown in FIG. 2B. Subsequently, the first through groove 70 has a shape along the inner periphery of the base 28, and the second through groove 71 has a shape along the outer periphery of the third object 22.

Additionally, an area 74 that is adjacent to the inner periphery of the first through groove 70 and adjacent to the outer periphery of the second through groove 71 is a beam area that makes the relative position between the first connection area 72 and the second connection area 73 in the Z-axis direction variable. The third plate spring 42 can cause an action as a spring due to the occurrence of the displacement in the Z-axis direction, that is, the occurrence of deflection, in the beam area 74.

By forming each of the plate springs 40, 41, and 42 as described above, the second object 21 is first held so as to be interposed between the first plate spring 40 and the second plate spring 41 in the Z-axis direction, and it is supported by the third object 22 via the first plate spring 40 and the second plate spring 41. Subsequently, the second beam area 12 of the first plate spring 40 and the beam area 64 of the second plate spring 41, both of which are elastic displacement parts, correspond as the second spring mechanism 23. In contrast, the third object 22 is held so as to be interposed between the first plate spring 40 and the third plate spring 42 in the Z-axis direction, and it is supported by the base 28 via the first plate spring 40 and the third plate spring 42. Subsequently, the first beam area 11 in the first plate spring 40 and the beam area 64 in the second plate spring 41, both of which are elastic displacement parts, correspond as the third spring mechanism 24.

Here, in order to perform control (isolate vibration) up to lower-frequency vibration by using the vibration control device 80 including the reference portion 30, it is desirable to lower the natural frequency of the vibration control device 80, that is, the natural frequency in the reference portion 30. First, in order to lower the natural frequency in the second spring mechanism 23 inside the reference portion 30, it is desirable that a length of the second beam area 12 in the first plate spring 40, that is, a distance between one end that communicates to the second connection area 15 and the other end that communicates to the third connection area 16, is long. However, for example, handling this simply by forming the second beam area 12 long in the radiation direction is difficult because of spatial restrictions. Accordingly, in the present embodiment, as shown in FIGS. 3A to 3C, the third through grooves 52 and the fourth through grooves 53 are concentrically formed around the reference axis, and a plurality of communication parts that communicate the areas adjacent to each other is provided at fixed intervals. In the example of the first plate spring 40 shown in FIGS. 3A to 3C, the third through groove 52 and the fourth through groove 53 include communication parts at three locations at 120° intervals to each other. Moreover, the first plate spring 40 further has communication grooves 13 that are adjacent to each of the communication parts at three locations, and connects the third through grooves 52 and the fourth through grooves 53. In particular, in the example of the first plate spring 40 shown in FIGS. 3A to 3C, the counterclockwise side ends of the third through grooves 52 and the clockwise side ends of the fourth through grooves 53 are connected through the communication grooves 13.

Additionally, in relation to the second spring mechanism 23, and also regarding the beam area 64 in the second plate spring 41, the relations between the first through grooves 60 and the second through grooves 61 are basically similar to the above described relations between the third through grooves 52 and the fourth through grooves 53. However, in the example of the second plate spring 41 shown in FIGS. 4A and 4B, contrary to the case described above, the clockwise side ends of the first through grooves 60 and the counterclockwise side ends of the second through grooves 61 are connected through communication grooves 65. Moreover, it is assumed that the reference portion 30 (first plate spring 40) is seen from the positive side of the Z-axis direction. At this time, the communication parts at three locations between the third through grooves 52 and the fourth through grooves 53 in the first plate spring 40 and the communication parts at three locations between the first through grooves 60 and the second through grooves 61 in the second plate spring 41 do not overlap in the XY-plane (they are at different positions each other in a plane perpendicular to the displacement direction). Specifically, as seen from the comparison of FIGS. 3A to 3C, and FIGS. 4A and 4B, for example, the communication parts in the second plate spring 41 are positioned so as to be shifted (rotated) at 60° around the reference axis with respect to the disposed position of the communication parts in the first plate spring 40.

In contrast, also regarding lowering the natural frequency in the third spring mechanism 24 inside the reference portion 30, it is desirable to lengthen the length of the first beam area 11 in the first plate spring 40 in a manner similar to the above described second spring mechanism 23. Accordingly, also in here, as shown in FIGS. 3A to 3C, the first through grooves 50 and the second through grooves 51 are concentrically formed around the reference axis, and a plurality of communication parts that communicate the areas adjacent to each other at fixed intervals is provided. However, with regards to the third spring mechanism 24, unlike the second spring mechanism 23, the first through grooves 50 and the second through grooves 51 are not connected. Additionally, the first through grooves 60 include a plurality of communication parts that communicate areas adjacent each other at fixed intervals. In the example of the first plate spring 40 as shown in FIGS. 3A to 3C, the first through grooves 50 include communication parts at three locations at 120° intervals, and the second through grooves 51 also include the communication parts at three locations at 120° intervals, wherein each angle position shifts (rotates) 60° around the reference axis.

Additionally, in relation to the third spring mechanism 24, also regarding the beam area 74 in the third plate spring 42, the relation between the first through groove 70 and the second through groove 71 is basically similar to the above described relation between the first through groove 50 and the second through groove 51. Here, it is assumed that the reference portion 30 (first plate spring 40) is seen from the positive side of the Z-axis direction. At this time, the communication parts at three locations between the first through grooves 50 and the second through grooves 51 in the first plate spring 40 and the communication parts at three locations between the first through grooves 60 and the second through grooves 61 in the third plate spring 42 do not overlap in the XY-plane. Specifically, as seen from the comparison of FIGS. 3A to 3C, and FIGS. 4A and 4B, for example, the communication parts in the third plate spring 42 are positioned shifted (rotated) at 60° around the reference axis, with respect to the disposed position of the communication parts in the first plate spring 40.

Note that, in order to lower the natural frequency of the reference portion 30, or in order to obtain the desired natural frequency, the shape, the thickness, or the material of the components for the second spring mechanism 23 or the third spring mechanism 24 may be individually changed as needed. Specifically, that Young's modulus of the third spring mechanism 24 may be made larger than that of the second spring mechanism 23, or the thickness of the third spring mechanism 24 may be made thicker than that of the second spring mechanism 23. At this time, in the above explanation, although the first plate spring 40 is uniformly formed including the components for the second spring mechanism 23 and the third spring mechanism 24, it may have a configuration in which a first component that configures the second spring mechanism 23 and a second component that configures the third spring mechanism 24 are separate. Moreover, in the above explanation, although the second object 21 and the third object 22 are configured to be interposed between each of the plate springs at the respective ends (end faces) thereof in the Z-axis direction, the present invention is not necessarily limited to the ends, and they may be configured such that at least apart of the second object 21 and the third object 22 is interposed by each of the plate springs. Additionally, the aforementioned configuration of the reference portion 30 regulates the reference position in the Z-axis direction, and configures the detecting system that detects the position of the first object 2. A configuration in which this configuration is rotated at 90° around the X-axis or the Y-axis to regulate it as a position reference in the X-axis direction or the Y-axis direction is allowed.

FIGS. 6A to 6C are schematic side diagrams for explaining a vibration mode that can occur in the reference portion 30. In the reference portion 30, the following two vibration modes that accompany different motions each other can occur. First, a first vibration mode is a vibration mode in which the second object 21 and the third object 22 accompany translation motions along the reference axis (that is, in the direction detected by the first detector 31). In contrast, a second vibration mode is a vibration mode in which the second object 21 and the third object 22 accompany tilt motions with respect to the reference axis (that is, the motion in which the detected direction by the first detector 31 is inclined). FIG. 6A illustrates the reference portion 30 in a stationary state, FIG. 6B illustrates the reference portion 30 in the first vibration mode, and FIG. 6C illustrates the reference portion 30 in the second vibration mode. Because the second object 21 and the third object 22 are respectively supported at a plurality of positions (two positions in the present embodiment) in the Z-axis direction, the displacement direction is properly regulated in the Z-axis direction (measurement direction) when displacement is caused by the first vibration mode.

In contrast, when the second vibration mode as shown in FIG. 6C occurs, the natural frequency of the second vibration mode is desirably higher than that of the first vibration mode. The reference portion 30 inputs the relative displacement detected at the first detector 31 to the first compensator 5, and performs feedback control that transmits to the second driving unit 33 an operation amount such that the relative displacement becomes a fixed value. Accordingly, if a control band of a servomotor control frequency of the first feedback control system is, for example, between 50 and 60 Hz, the natural frequency of the first vibration mode is set lower than the servomotor control frequency (for example, 60 Hz that is the upper frequency of the control band). That is, the servomotor control frequency of the first feedback control system is desirably higher than the natural frequency of the first vibration mode. In contrast, in this case, the servomotor control frequency of the first feedback control system is desirably lower than the natural frequency of the second vibration mode, and it is desirably one-half or less of the natural frequency of the second vibration mode. Subsequently, in the present embodiment, in the second spring mechanism 23 and the third spring mechanism 24, as described above, the shape of each of the through grooves is reversed between the plate spring positioned at the positive side of the Z-axis direction and the plate spring positioned at the negative side of the Z-axis direction, or each position of the grooves is shifted around the reference axis. This configuration and shape make it possible to suppress the natural frequency of the second vibration less from becoming lower than the natural frequency of the first vibration mode. Alternatively, for example, there may be a configuration in which a guide mechanism such as a linear guide is provided in at least one of either of the second spring mechanism 23 or the third spring mechanism 24, so that the lowering of the natural frequency of the second vibration mode is suppressed.

Thus, the miniaturization of the reference portion 30 can be realized by forming the shape of each component and the like as described above. Additionally, the second spring mechanism 23 and the third spring mechanism 24 are configured in particular by the plurality of springs 40, 41, and 42, so that the reference portion 30 can further lower its own its natural frequency. Additionally, the first vibration mode and the second vibration mode that accompany different respective motions can occur in the reference portion 30, wherein the reference portion 30 can further lower the natural frequency of the first vibration mode by configuring the second spring mechanism 23 and the third spring mechanism 24 as described above. Moreover, the second spring mechanism 23 and the third spring mechanism 24 are configured as described above, so that the reference portion 30 is allowed to make the natural frequency of the second vibration mode higher than the upper frequency of the control band of the first feedback control system. Therefore, oscillation that may occur during the feedback control in the first feedback control system can be suppressed.

As described above, according to the present embodiment, the vibration control device that controls the vibration of the object to be controlled by using the two-degree-of-freedom system and that is advantageous in the suppression of the oscillation can be provided. Moreover, according to the lithography apparatus 100 including this vibration control device, the influence of the floor vibration can be further reduced.

### (Article Manufacturing Method)

A method of manufacturing an article according to an embodiment of the present invention is suitable for manufacturing an article such as a microdevice (for example, a semiconductor device) or an element having a microstructure. This manufacturing method can include a step of forming a pattern (for example, a latent image pattern) on an object (for example, a substrate having a photosensitive agent on the surface) by using the above-described lithography apparatus, and a step of processing the object on which the pattern is formed (for example, a developing step). Further, this manufacturing method includes other well-known steps (for example, oxidization, deposition, vapor deposition, doping, planarization, etching, resist removal, dicing, bonding, packaging and the like). The method of manufacturing an article according to the embodiment is superior to a conventional method in at least one of the performance, quality, productivity, and production cost of the article.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2014-148536 filed Jul. 22, 2014, which is hereby incorporated by reference herein in its entirety.

What is claimed is:

1. A vibration control device comprising:
a first object;
a first spring mechanism for supporting the first object;
a detecting system for detecting a position of the first object; and
a first driving member for applying force to the first object,
wherein the vibration control device is configured to control the first driving member based on the output of the detecting system to control vibration of the first object,
wherein the detecting system includes:
a second object;
a second spring mechanism that supports the second object;
a third object that supports the second spring mechanism;
a third spring mechanism that supports the third object;
a first detector that detects displacement of the third object with respect to the second object;
a second driving member that applies a force to the third object; and
a feedback control member that is configured to perform feedback control on the second driving member based on the output of the first detector,
wherein a two-degree-of-freedom system including the second object and the third object vibrates by a first vibration mode that accompanies a translation motion and a second vibration mode that accompanies a tilt motion, according to a natural frequency, and
wherein a servomotor control frequency of the feedback control member is higher than the natural frequency of the first vibration mode and lower than the natural frequency of the second vibration mode.

2. The vibration control device according to claim 1, wherein the servomotor controls frequency is one-half or less of the natural frequency of the second vibration mode.

3. A vibration control device comprising:
a first object;
a first spring mechanism for supporting the first object;
a detecting system for detecting a position of the first object; and
a first driving member for applying force to the first object,
wherein the vibration control device is configured to control the first driving member based on the output of the detecting system to control vibration of the first object,
wherein the detecting system includes:
a second object;
a second spring mechanism that supports the second object;
a third object that support the second spring mechanism;
a third spring mechanism that supports the third object;
a base that supports the third spring mechanism, a detector that detects displacement of the third object with respect to the second object;
a second driving member that applies a force to the third object; and
a feedback control member that is configured to perform feedback control on the second driving unit based on the output of the detector,
wherein the third object is configured to cover a side face of the second object,
wherein the base is configured to cover a side face of the third object,
wherein the second spring mechanism connects the second object and the third object, and has a plate spring onto which a through groove along the outer periphery of the second object and a through groove along the inner periphery of the third object are formed, and
wherein the third spring mechanism connects the third object and the base, and has a plate spring onto which a through groove along the outer periphery of the third object and a through groove along the inner periphery of the base are formed.

4. The vibration control device according to claim 3, wherein the shape of the through grooves is concentric to the reference axis.

5. The vibration control device according to claim 3, wherein an area where the plate spring is displaced has a communication groove that connects a clockwise side end of the through groove and a counterclockwise side end of the through groove, in the through groove along the outer periphery or the through groove along the inner periphery that are adjacent to the respective areas.

6. The vibration control device according to claim 3, wherein the number of the plate spring included in the second spring mechanism or the third spring mechanism is more than one in accordance with a plurality of different positions in a displacement direction,
wherein the through groove included in one of the plate spring and the through groove included in the other plate spring face each other in the displacement direction, and
wherein a communication part that communicates two areas adjacent each other to the through groove included in the one plate spring and a communication part that communicates two areas adjacent each other to the through groove included in the other plate spring are at respectively different positions in a plane perpendicular to the displacement direction.

7. The vibration control device according to claim 5, wherein the communication groove included in the one plate spring connects the clockwise side end of the one through groove and the counterclockwise side end of the other through groove, in the through groove along the outer periphery and the through groove along the inner periphery, and
wherein the communication groove included in the other plate spring connects the counterclockwise side end of the one through groove and the clockwise side end of the other through groove, in the through groove along the outer periphery and the through groove along the inner periphery.

8. The vibration control device according to claim 3, wherein Young's modulus of the plate spring that configures the third spring mechanism is larger than that of the plate spring that configures the second spring mechanism.

9. The vibration control device according to claim 3, wherein the thickness of the plate spring that configures the third spring mechanism is larger than that of the plate spring that configures the second spring mechanism.

10. The vibration control device according to claim 3, including a guide mechanism that guides translation of the second object and the third object.

11. A lithography apparatus for patterning a substrate, the lithography apparatus comprising:
a supporting unit that supports at least a part of a processing unit that forms the pattern; and
a vibration control device comprising:
the processing unit serving as a first object;
a first spring mechanism for supporting the first object;
a detecting system for detecting a position of the first object; and
a first driving member for applying force to the first object,
wherein the vibration control device is configured to control the first driving member based on the output of the detecting system to control vibration of the first object,
wherein the detecting system includes:
a second object;
a second spring mechanism that supports the second object;
a third object that supports the second spring mechanism;
a third spring mechanism that supports the third object;
a first detector that detects displacement of the third object with respect to the second object;
a second driving member that applies a force to the third object; and
a feedback control member that is configured to perform feedback control on the second driving member based on the output of the first detector,
wherein a two-degree-of-freedom system including the second object and the third object vibrates by a first vibration mode that accompanies a translation motion and a second vibration mode that accompanies a tilt motion, according to a natural frequency, and
wherein a servomotor control frequency of the feedback control member is higher than the natural frequency of the first vibration mode and lower than the natural frequency of the second vibration mode.

12. A lithography apparatus for patterning a substrate, the lithography apparatus comprising:
a supporting unit that supports at least a part of a processing unit that forms the pattern; and
a vibration control device comprising:
the processing unit serving as a first object;
a first spring mechanism for supporting the first object;
a detecting system for detecting a position of the first object; and
a first driving member for applying force to the first object,
wherein the vibration control device is configured to control the first driving member based on the output of the detecting system to control vibration of the first object,
wherein the detecting system includes:
a second object;
a second spring mechanism that supports the second object;
a third object that support the second spring mechanism;
a third spring mechanism that supports the third object;
a base that supports the third spring mechanism;
a detector that detects displacement of the third object with respect to the second object;
a second driving member that applies a force to the third object; and
a feedback control member that is configured to perform feedback control on the second driving unit based on the output of the detector,
wherein the third object is configured to cover a side face of the second object,
wherein the base is configured to cover a side face of the third object,
wherein the second spring mechanism connects the second object and the third object, and has a plate spring onto which a through groove along the outer periphery of the second object and a through groove along the inner periphery of the third object are formed, and
wherein the third spring mechanism connects the third object and the base, and has a plate spring onto which a through groove along the outer periphery of the third object and a through groove along the inner periphery of the base are formed.

13. A method of manufacturing an article, the method comprising steps of:
patterning a substrate by using a lithography apparatus, processing the patterned substrate,
wherein the lithography apparatus comprises:
a supporting unit that supports at least a part of a processing unit that forms the pattern; and
a vibration control device comprising:
the processing unit serving as a first object;
a first spring mechanism for supporting the first object;
a detecting system for detecting a position of the first object; and
a first driving member for applying force to the first object,
wherein the vibration control device is configured to control the first driving member based on the output of the detecting system to control vibration of the first object,
wherein the detecting system includes:
a second object;
a second spring mechanism that supports the second object;
a third object that supports the second spring mechanism;
a third spring mechanism that supports the third object;
a first detector that detects displacement of the third object with respect to the second object;
a second driving member that applies a force to the third object; and
a feedback control member that is configured to perform feedback control on the second driving member based on the output of the first detector,
wherein a two-degree-of-freedom system including the second object and the third object vibrates by a first vibration mode that accompanies a translation motion and a second vibration mode that accompanies a tilt motion, according to a natural frequency, and
wherein a servomotor control frequency of the feedback control member is higher than the natural frequency of the first vibration mode and lower than the natural frequency of the second vibration mode.

14. A method of manufacturing an article, the method comprising steps of:
patterning a substrate by using a lithography apparatus,
processing the patterned substrate,
wherein the lithography apparatus comprises:
a supporting unit that supports at least a part of a processing unit that forms the pattern; and
a vibration control device comprising:
the processing unit serving as a first object, a first spring mechanism for supporting the first object;
a detecting system for detecting a position of the first object; and
a first driving member for applying force to the first object,
wherein the vibration control device is configured to control the first driving member based on the output of the detecting system to control vibration of the first object,
wherein the detecting system includes:
a second object;
a second spring mechanism that supports the second object;
a third object that support the second spring mechanism;
a third spring mechanism that supports the third object;
a base that supports the third spring mechanism;
a detector that detects displacement of the third object with respect to the second object;
a second driving member that applies a force to the third object; and
a feedback control member that is configured to perform feedback control on the second driving unit based on the output of the detector,
wherein the third object is configured to cover a side face of the second object,
wherein the base is configured to cover a side face of the third object,
wherein the second spring mechanism connects the second object and the third object, and has a plate spring onto which a through groove along the outer periphery of the second object and a through groove along the inner periphery of the third object are formed, and
wherein the third spring mechanism connects the third object and the base, and has a plate spring onto which a through groove along the outer periphery of the third object and a through groove along the inner periphery of the base are formed.
